(19) United States
(12) Patent Application Publication
(10) Pub. No.: US 2001/0046750 A1
(43) Pub. Date: Nov. 29, 2001

(54) Method for manufacturing semiconductor device having a STI structure

(76) Inventors: Shuji Miyazaki, Tokyo (JP); Kensuke Okonogi, Tokyo (JP)

Correspondence Address: McGinn & Gibb, PLLC,, Suite 200, 8321 Old Courthouse Road, Vienna, VA, 22182-3817, US

(21) Appl. No.: 09/862,517

(22) Filed: May 23, 2001

(30) Foreign Application Priority Data
May 24, 2000 (JP) 2000-153019

(51) Int. Cl. H01L 21/76

(52) U.S. Cl. 438/400

(57) ABSTRACT

A method includes the step of forming a silicon oxide film and a silicon nitride film having an opening for exposing a portion of a silicon substrate, etching the portion of the silicon substrate to form a device isolation trench, widening the opening only at the silicon nitride film, thermally oxidizing the inner surface of the device isolation trench to form a thermal oxide film, depositing another silicon oxide film for filling the opening and the device isolation trench, etching the top portion of the another silicon oxide film and then the silicon nitride film, and polishing the another silicon oxide film and the silicon oxide film to obtain flat surfaces of the another silicon oxide film, the thermal oxide film and the silicon substrate.

### BACKGROUND OF THE INVENTION

1. Field of the Invention

The present invention relates to a method for manufacturing a semiconductor device having a STI structure. More particularly, the present invention relates to a method for manufacturing a semiconductor device in which it is possible to suppress the occurrence of divots in the STI structure.

2. Description of the Related Art

STI (Shallow Trench Isolation) structure has been used for providing an isolation between semiconductor elements in a semiconductor device. FIG. 1 is a sectional view illustrating a conventional semiconductor device, in which divots 18 occur on the surface of a silicon oxide film 17 in a device isolation trench 16. In the semiconductor device, the divots 18 are formed along the edges of the device isolation trench 16 on the upper surface of the silicon oxide film 17 deposited in the device isolation trench 16, which is formed in a silicon substrate 11. When the silicon oxide film 17 deposited in the device isolation trench 16 is etched, the divot 18 is formed as a result of over-etching occurring along the edges of the device isolation trench 16.

For a semiconductor device having an STI structure, it is important to suppress the occurrence of such divots in order to obtain desirable transistor characteristics. FIG. 2A to FIG. 2H are sectional views consecutively illustrating fabrication steps performed in a conventional fabrication process which is capable of reducing the occurrence of divots.

First, referring to FIG. 1A, a silicon oxide film 12 and a silicon nitride film 13 are deposited in this order on a single-crystalline silicon substrate 11. Then, a photoresist film 14 having a specified pattern is formed on the silicon nitride film 13, and the silicon nitride film 13 and the silicon oxide film 12 are subjected to an anisotropic etching process using the photoresist film 14 as a mask, thereby forming an opening through which the silicon substrate 11 is exposed.

Then, the photoresist film 14 is removed, and a silicon oxide film is deposited across the entire surface. The silicon oxide film is etched across the entire surface by a depth that is equal to the thickness of the silicon oxide film deposited on the silicon nitride film 13. As a result, a side wall silicon oxide film 15 is left on the side wall of the opening in the silicon nitride film 13, as illustrated in FIG. 2B. Then, the silicon substrate 11 is subjected to an anisotropic etching process using the silicon nitride film 13 and the side wall 15 as a mask so as to form the device isolation trench 16 of a specified depth, as illustrated in FIG. 2C. After the side wall film 15 is etched away, the silicon oxide film 17 is deposited across the entire surface so as to fill the opening and the device isolation trench 16, as illustrated in FIG. 2D. The thickness of the deposited silicon oxide film 17 has a thickness larger than the sum of the depth of the device isolation trench and the thicknesses of the silicon oxide film 12 and the silicon nitride film 13 at least at the device isolation trench.

Then, the silicon nitride film 13 and the silicon oxide film 17 are polished using a CMP (chemical-mechanical polishing) technique by a specified amount so that the surface of the exposed silicon nitride film 13 and the surface of the silicon oxide film 17 are flush with each other, as illustrated in FIG. 2E. Then, the silicon oxide film 17 is etched by a specified amount by using a hydrofluoric acid, or the like, as an etchant, as illustrated in FIG. 2F.

Then, the silicon nitride film 13 is selectively etched by using a phosphoric acid, or the like, as illustrated in FIG. 2G. As a result, the width “B” of the surface of the silicon oxide film 17 is made larger than the width “A” of the device isolation trench 16. Then, the silicon oxide film 12 and the silicon oxide film 17 are etched by using a hydrofluoric acid, or the like, as illustrated in FIG. 2H. Since the etching is performed on the surface of the silicon oxide film 17 whose width “B” is larger than the width “A” of the device isolation trench 16, the over-etching does not occur along the edges of the device isolation trench 16, thereby preventing the occurrence of divots.

In the conventional fabrication method as described above, an etching damage 11a, as illustrated in FIG. 2A, occurs on the silicon substrate 11 during the etching process using the photoresist film 14 as a mask. The etching damage 11a is covered by the side wall film 15 in the step of FIG. 2B, and the device isolation trench 16 is formed with the etching damage 11a remaining intact, as illustrated in FIG. 2C. Since the inside of the device isolation trench 16 and the edges of the device isolation trench 16 are covered by the silicon oxide film 17, the process proceeds with the etching damage 11a remaining along the edges of the device isolation trench 16 to the fabrication step of FIG. 2H. Subsequently, a gate oxide film is formed in the area along each edge of the device isolation trench 16 with the etching damage 11a remaining therein. The etching damage causes degradation of the characteristics of the MOS transistor formed in the etching-damaged area.

One possible way to avoid the above-described problem is to recover the etching damage 11a before proceeding to the next step. However, it increases the fabrication steps, e.g., the steps of oxidizing the etching-damaged area to a specified depth to form a thermal oxide film and then etching the resulting oxide film with a hydrofluoric acid. It can be said that the etching damage either complicates the fabrication process, or reduces the throughput of the semiconductor devices.

In addition, with the conventional fabrication method described above, a high dimensional accuracy is required for the side wall film 15, which is used as a mask when forming the device isolation trench 16, in order to obtain accurate dimensions for the device isolation trench 16t. If an oxide film to be formed as the side wall film 15 is grown by a low-pressure chemical vapor deposition (LPCVD) so as to satisfy the dimensional requirement, the growth takes a long time, thereby leading to a further reduction in the throughput.

### SUMMARY OF THE INVENTION

In view of the above, it is an object of the present invention to provide a method for manufacturing a semiconductor device, with which it is possible to obtain a device area for forming a gate oxide film therein with little etching damage remaining therein, while suppressing the occurrence of divots, without requiring an additional step, and which simplifies the fabrication process as compared with the conventional fabrication method forming a side wall film, thereby allowing for fabrication of semiconductor devices with a higher throughput.

The present invention provides a method for fabricating a semiconductor device including the steps of: consecutively forming first and second insulator films on a semiconductor substrate; forming an opening penetrating through the first and second insulator films; etching the semiconductor substrate by using the first and second insulator films as a mask to form a device isolation trench in alignment with the opening; thermally treating the semiconductor substrate to form a thermal oxide film on an inner surface of the device isolation trench, the thermal oxide film having an edge coupled to the first insulator film; widening the opening at the second insulator film to have a width larger than a width of the device isolation trench; depositing a third insulator film on the second insulator film and within the opening and the device isolation trench, the third insulator film having a top surface above the device isolation trench which top surface is higher than a top surface of the second insulator film; etching the third insulator film to leave a portion of the third insulator film in the opening and the device isolation trench; etching the second insulator film to expose the portion of the third insulator film above the first insulator film; and etching the portion of the third insulator film and the first insulator film to obtain an equal level of a top surface of the portion of the third insulator film and exposed top surfaces of the thermal oxide film and the semiconductor substrate.

In accordance with the method for manufacturing a semiconductor device of the present invention, it is possible to obtain the device area for forming a gate oxide film substantially without etching damages remaining in the device area and without an additional step while suppressing the occurrence of divots on the silicon oxide film in the device isolation trench. Moreover, it is possible to simplify the fabrication process as compared with the conventional fabrication method using a side wall film, thereby allowing the fabrication of semiconductor devices to have a higher throughput.

### BRIEF DESCRIPTION OF THE DRAWINGS

FIG. 1 is a sectional view illustrating a conventional semiconductor device having an STI structure in which divots occur on the surface of a silicon oxide film deposited in a device isolation trench;

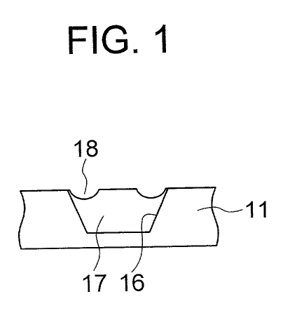

FIG. 2A to FIG. 2H are sectional views consecutively illustrating steps performed in a conventional fabrication method which is capable of reducing the occurrence of divots.

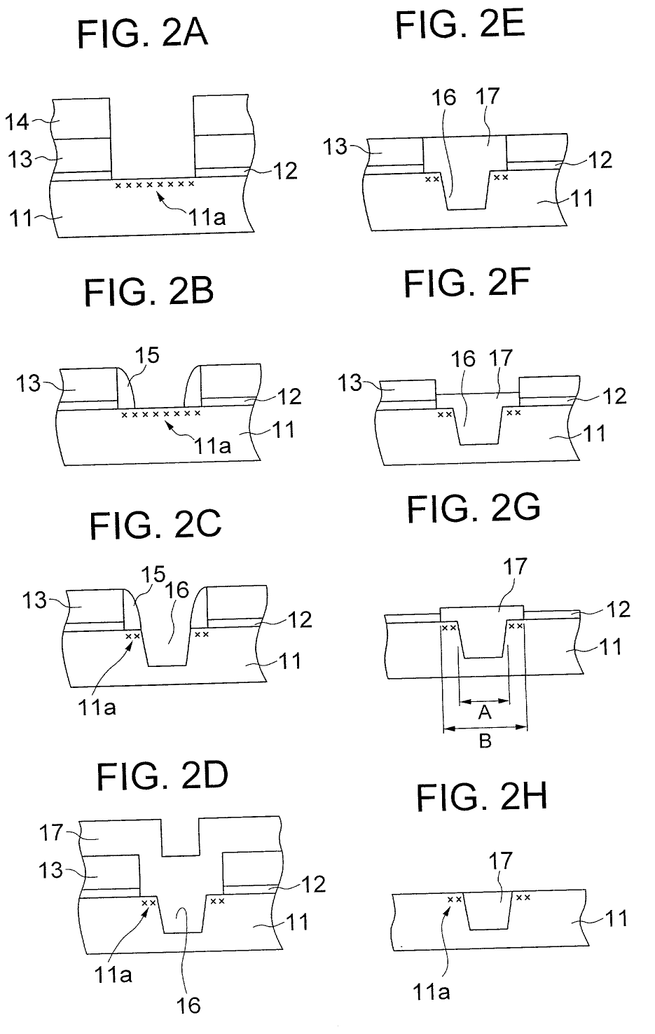

FIG. 3A to FIG. 3I are sectional views consecutively illustrating steps performed in a method for manufacturing a semiconductor device according to a first embodiment of the present invention; and

FIG. 4A to FIG. 4E are sectional views consecutively illustrating steps performed in a method for manufacturing a semiconductor device according to a second embodiment of the present invention;

### DETAILED DESCRIPTION OF THE PREFERRED EMBODIMENTS

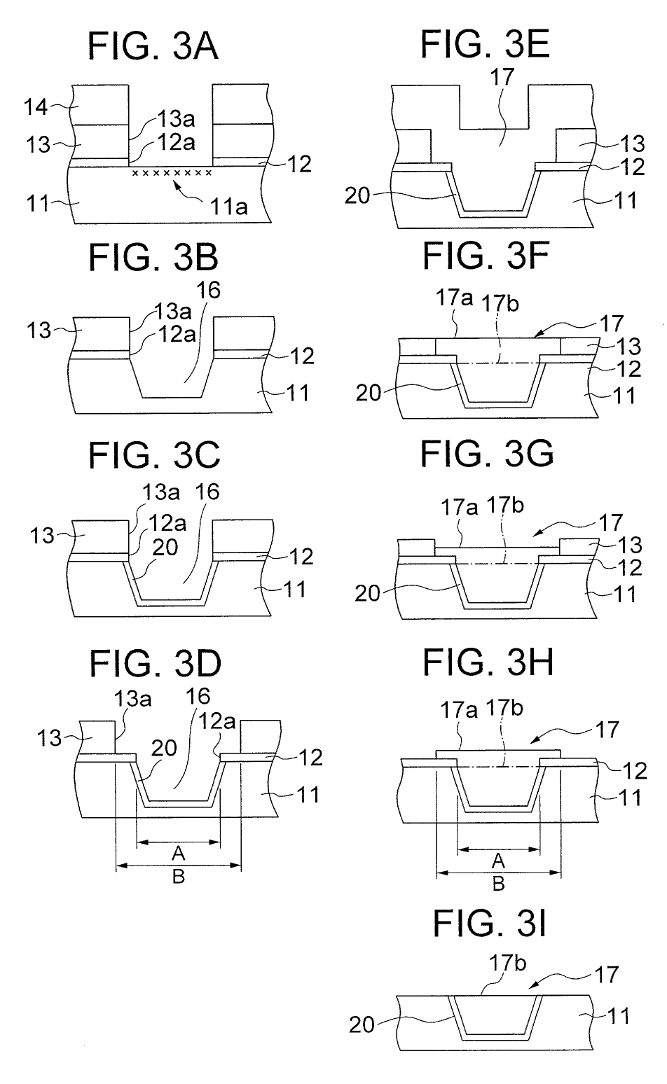

The present invention will now be described in more detail based on preferred embodiments of the present invention with reference to the accompanying drawings, wherein similar constituent elements are designated by similar reference numerals throughout the drawings. FIG. 3A to FIG. 3I are sectional views consecutively illustrating fabricating steps performed in a method for manufacturing a semiconductor device according to the first embodiment of the present invention.

First, referring to FIG. 3A, a silicon oxide film (first insulator film) 12 having a thickness of 5 to 30 nm, for example, and a silicon nitride film (second insulator film) 13 having a thickness of 100 to 300 nm are deposited in this order on a single-crystalline silicon substrate 11, and a photoresist film 14 is deposited on the silicon nitride film 13. Then, the photoresist film 14 is patterned to have a specified pattern by photolithography, and the silicon nitride film 13 and the silicon oxide film 12 are both subjected to an anisotropic etching process using the photoresist film 14 as a mask, thereby forming a circuit pattern on the device area. Thus, openings 12a and 13a penetrating through the silicon oxide film 12 and the silicon nitride film 13, respectively, are formed in each area where a device isolation trench 16 is to be formed.

Then, after the photoresist film 14 is removed, the silicon substrate 11 is subjected to an anisotropic etching process using the silicon nitride film 13 and the silicon oxide film 12 as a mask, thereby forming the device isolation trench 16 having a depth of 100 to 400 nm, for example, as illustrated in FIG. 3B. Alternatively, the photoresist film 14 may be left unremoved, and the photoresist film 14 may be used as a mask in the step of forming the device isolation trench 16.

Substrates, a thermal oxide film 20 having a thickness of 10 to 40 nm, for example, is formed on the inner surface of the device isolation trench 16 so that the thermal oxide film 20 is coupled to the opening 12a of the silicon oxide film 12, as illustrated in FIG. 3C, in an ambient containing H₂+O₂+N₂, O₂+N₂ or a halide gas and at a temperature of 850 to 1100° C. Then, an oxide film that has been formed on the surface of the silicon nitride film 13 during the formation of the thermal oxide film 20 is removed using a hydrofluoric acid at a low etching rate.

Then, a wet etching process using a phosphoric acid or an isotropic dry etching process is performed to selectively remove the side walls of the opening 13a of the silicon nitride film 13 by an amount of 10 to 40 nm so as to retract the silicon nitride film 13 away from the edges of the device isolation trench 16 in a direction parallel to the substrate surface, as illustrated in FIG. 3D. As a result, the opening 13a has a larger width “B”, which is larger than the width “A” of the device isolation trench 16.

Thereafter, by using a method for achieving a desirable step coverage, such as a LPCVD technique, a silicon oxide film 17 having a thickness of 500 nm, for example, is grown across the entire surface of the silicon substrate 11, including the inner surface of the device isolation trench 16 and the opening 13a, so as to fill the opening 13a and the device isolation trench 16 and cover the upper surface of the silicon nitride film 13, as illustrated in FIG. 3E.

Then, the silicon oxide film 17 and the silicon nitride film 13 are polished together using a CMP process by a specified amount to obtain a flat surface such that the silicon oxide film 17 and the exposed silicon nitride film 13 are flush, as illustrated in FIG. 3F. In the present embodiment, it is determined that the height from the level of the device area surface 7b of the silicon substrate 11 to the surface 17a of the silicon oxide film 17 is 150 nm. The silicon nitride film 13 has a function as a stopper for the polishing process as well as its function as a mask.

Subsequently, the silicon oxide film 17 is etched by a specified amount by a selective etching process using a hydrofluoric acid, or the like, so as to adjust the height of the surface 17a of the silicon oxide film 17 from the device area surface 17b, as illustrated in FIG. 3G. Then, the silicon nitride film 13 is selectively removed by an etching process using a phosphoric acid, or the like, so as to obtain the silicon oxide film 17 having a surface width substantially equal to the width “B” of the opening 13a, as illustrated in FIG. 3H.

Then, the silicon oxide film 12 and an top portion of the silicon oxide film 17 are removed by an etching process using a hydrofluoric acid so that the surface 17a of the silicon oxide film 17, the top surface of the thermal oxide film 20 and the surface of the silicon substrate 11 have the same level, as illustrated in FIG. 3I. By using such an etching process, the surface portion of the silicon oxide film 17 having the width “B”, which extends beyond the width “A” of the device isolation trench 16, can be removed together with the silicon oxide film 12, whereby the over-etching along the edges of the device isolation trench 16, and thus the occurrence of divots, are prevented.

Moreover, even if an etching damage 11a occurs on the silicon substrate 11 during the formation of the openings 12a and 13a in the silicon oxide film 12 and the silicon nitride film 13, the etching damage 11a is removed when the device isolation trench 16 is formed by using the silicon oxide film 12 and the silicon nitride film 13 as a mask. Then, the process proceeds to the final etching step of FIG. 3I while maintaining the damage-free state of the silicon substrate 11 and protecting the inner surface of the device isolation trench 16 as well as the vicinity thereof by the thermal oxide film 20 and the silicon oxide film 12, with the edge of the thermal oxide film 20 being coupled to the silicon oxide film 12. Thus, it is possible to obtain a device area for forming a gate oxide film, substantially without etching damage 11a remaining therein, and without using an additional process. Moreover, it is possible to simplify the fabrication process as compared with the conventional fabrication method using a side wall film, thereby allowing for fabrication of a semiconductor device with a higher throughput.

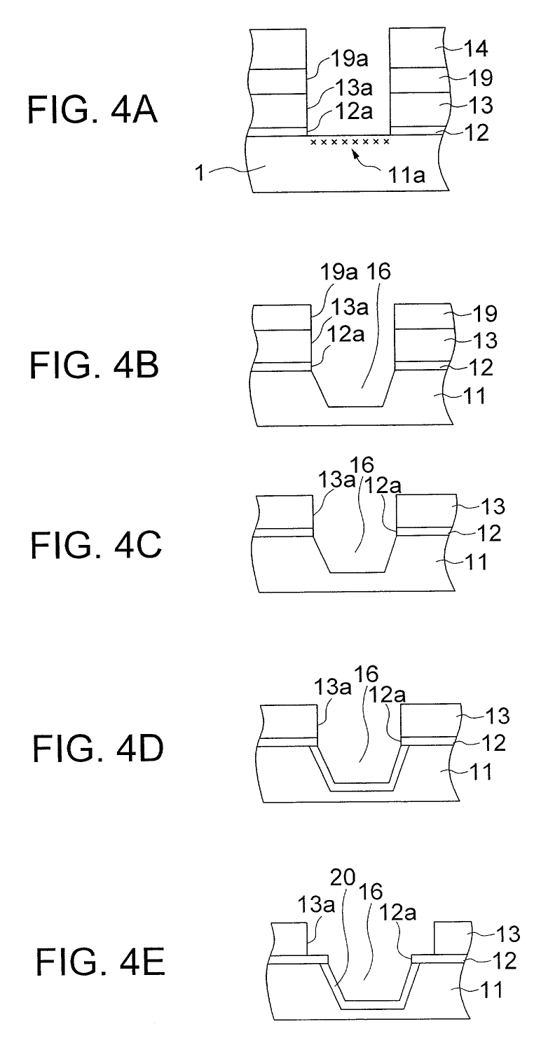

Now, a second embodiment of the present invention will be described hereinafter. FIG. 3A to FIG. 3E are sectional views consecutively illustrating fabrication steps in a method for manufacturing a semiconductor device according to the present embodiment. The series of steps shown in FIG. 4A to FIG. 4E corresponds to the series of steps shown in FIG. 3A to FIG. 3D. The drawings for illustrating the steps following the step of FIG. 4E are omitted herein for avoiding a duplication because these steps are similar to those in the first embodiment.

First, referring to FIG. 4A, a silicon oxide film 12 having a thickness of 5 to 30 nm, for example, a silicon nitride film 13 having a thickness of 100 to 300 nm, and a silicon oxide film 19 having a thickness of 5 to 30 nm are deposited in this order on a single-crystalline silicon substrate 1, and a photoresist film 14 is deposited on the silicon oxide film 19. Then, the photoresist film 14 is patterned to have a specified pattern by photolithography, and the silicon oxide film 19, the silicon nitride film 13 and the silicon oxide film 12 are subjected to an anisotropic etching process using the photoresist film 14 as a mask. Thus, openings 19a, 13a and 12a penetrating through the silicon oxide film 19, the silicon nitride film 13 and the silicon oxide film 12, respectively, are formed in each area where a device isolation trench 16 is to be formed.

Then, after the photoresist film 14 is removed, the silicon substrate 11 is subjected to an anisotropic etching process using the silicon oxide film 19, the silicon nitride film 13 and the silicon oxide film 12 as a mask, thereby forming the device isolation trench 16 having the same depth as in the first embodiment, as illustrated in FIG. 4B. As in the case of the first embodiment, the photoresist film 14 may alternatively be left unremoved, and the photoresist film 14 may be used as a mask in the step of forming the device isolation trench 16.

Subsequently, the silicon oxide film 19 is removed by an etching process using a hydrofluoric acid so as to expose the silicon nitride film 13, as illustrated in FIG. 4C. Alternatively, the silicon oxide film 19 may be removed before the formation of the device isolation trench 16, in which case the device isolation trench 16 may be formed by using the silicon nitride film 13 as a mask.

Thereafter, a thermal oxide film 20 having a thickness of 10 to 40 nm, for example, is formed on the inner surface of the device isolation trench 16 so that the thermal oxide film 20 is coupled to the opening 12a of the silicon oxide film 12, as illustrated in FIG. 3D, in an ambient and at temperature, which are similar to those in the first embodiment. Then, an oxide film that has been formed on the surface of the silicon nitride film 13 during the formation of the thermal oxide film 20 is removed using a hydrofluoric acid at a low etching rate.

Then, as in the case of the first embodiment, the side walls of the opening 13a of the silicon nitride film 13 are selectively etched so as to retract the edges of the silicon nitride film 13 away from the device isolation trench 16 in a direction parallel to the substrate surface, as illustrated in FIG. 4E. As a result, the width of the opening 13a is increased to have a larger width for the device isolation trench 16. Thereafter, steps similar to those of the first embodiment illustrated in FIG. 3E to FIG. 3I are performed.

While ensuring advantageous effects as those of the first embodiment, the present embodiment additionally provides an advantageous effect of suppressing the wearing out of the silicon nitride film, which may occur when a photoresist film is repeatedly formed and removed or when performing a silicon etching process, through the formation of the silicon oxide film 19 on the silicon nitride film 3 in the step of FIG. 4A.

While the present invention is described above with respect to the preferred embodiments thereof, the method for manufacturing a semiconductor device of the present invention is not limited to those embodiments described above, and various modifications or alterations can be made to the semiconductor device fabrication methods of the embodiments described above without departing from the scope of the present invention.

What is claimed is:

1. A method for fabricating a semiconductor device comprising the steps of:
consecutively forming first and second insulator films on a semiconductor substrate;
forming an opening penetrating through said first and second insulator films;
etching said semiconductor substrate by using said first and second insulator films as a mask to form a device isolation trench in alignment with said opening;
thermally treating said semiconductor substrate to form a thermal oxide film on an inner surface of said device isolation trench, said thermal oxide film having an edge coupled to said first insulator film;
widening said opening at said second insulator film to have a width larger than a width of said device isolation trench;
depositing a third insulator film on said second insulator film and within said opening and said device isolation trench, said third insulator film having a top surface above said device isolation trench which top surface is higher than a top surface of said second insulator film;
etching said third insulator film to leave a portion of said third insulator film in said opening and said device isolation trench;
etching said second insulator film to expose said portion of said third insulator film above said first insulator film; and
etching said portion of said third insulator film and said first insulator film to obtain an equal level of a top surface of said portion of said third insulator film and exposed top surfaces of said thermal oxide film and said semiconductor substrate.

2. The method as defined in claim 1, wherein said first and second insulator films are a silicon oxide film and a silicon nitride film, respectively.

3. The method as defined in claim 1, wherein said first insulator film is made of silicon oxide and said second insulator film includes a silicon nitride film and a silicon oxide film, which are consecutively formed on said first insulator film.

4. The method as defined in claim 1, wherein said thermally treating step is conducted at a temperature of 850 to 1100° C. to obtain a thickness of 10 to 40 nm for said thermal oxide film.
